(19) United States
(12) Patent Application Publication
(10) Pub. No.: US 2005/0286223 A1
(43) Pub. Date: Dec. 29, 2005

(54) Electronic device baffle

(76) Inventor: Ralph G. Morales, Tampa, FL (US)

Correspondence Address: LITMAN LAW OFFICES, LTD, PO BOX 15035, CRYSTAL CITY STATION, ARLINGTON, VA, 22215, US

(21) Appl. No.: 11/159,222

(22) Filed: Jun. 23, 2005

Related U.S. Application Data
(60) Provisional application No. 60/582,074, filed on Jun. 24, 2004.

(51) Int. Cl. H05K 7/20

(52) U.S. Cl. 361/690; 312/236

(57) ABSTRACT

The electronic device baffle is a device that is placed within or on top of the housing of an electronic device having a vented cover and electronic motherboard. The baffle is mounted to the vented cover, either above the cover or below the cover, and is situated above the motherboard. The baffle is designed to prohibit contaminants from contacting the motherboard without restricting the necessary flow of air through the vented cover. The baffle has sidewalls and a plurality of legs that may be attached to the sidewalls. The legs are affixed to the top or the bottom of the vented cover and support the baffle above the motherboard.

### CROSS-REFERENCE TO RELATED APPLICATION

This application claims the benefit of U.S. Provisional Patent Application Ser. No. 60/582,074, filed Jun. 24, 2004.

### BACKGROUND OF THE INVENTION

1. Field of the Invention

The present invention relates to vent systems with baffles, and more particularly to a baffle for use with an electronic device.

2. Description of the Related Art

Cable converters and satellite receivers are used in combination with television sets to provide programming to numerous households. Dust, liquid and other contaminants often enter through the air vent covers of the converters or receivers. These contaminants accumulate inside the motherboard, causing damage to the circuitry. The cable converters and satellite receivers are, therefore, unable to function correctly and have to be repaired.

Additionally, when contaminants enter into the cable converter or satellite receiver and disrupt the motherboard, the individual or repairman is not able to easily see that the contaminants have caused the problem. This forces the repairman to open the converter or receiver and examine the motherboard to determine the source of the problem.

There is a need for a device that prevents dust and other contaminants from accumulating within the motherboard in a cable converter, satellite receiver or the like. The related art shows baffles used in a variety of devices, but fails to show baffles used to prevent dust and other contaminants from collecting on the motherboard of an electronic device.

U.S. patent Publication No. 2003/0156385, published Aug. 21, 2003 and applied for by R. Askeland et al., describes a means to control thermal, acoustic, and/or electromagnetic characteristics of a computer. The computer has a housing with an area containing a motherboard assembly. A baffle is provided within the housing to control air movement as air passes into and exits from the housing.

U.S. patent Publication No. 2002/0121360, published Sep. 5, 1002 and applied for by D. Curry, describes an apparatus for heating white water with superheated steam. Baffle trays within the apparatus filter material contaminants from the white water.

U.S. Pat. No. 5,292,282, issued Mar. 8, 1994 to M. Callas, describes an air guard assembly. The assembly is magnetically attached to metal ceiling strips adjacent to an overhead air diffuser. The assembly contains a plurality of air baffles that direct the flow of air from the air diffuser toward the floor.

Other patents showing air vent baffles or the like include U.S. patent Publication No. 2003/0111062, published Jun. 19, 2003 and applied for by B. Brandenburg et al. (pressure actuated fuel vent closure and fuel shutoff apparatus); U.S. patent Publication No. 2003/0173365, published Sep. 18, 2003 and applied for by M. Stickel (fuel tank having a venting system); U.S. Pat. No. 3,950,151, issued Apr. 13, 1976 to R. Martin (pollution control apparatus and method); U.S. Pat. No. 4,094,437, issued Jun. 13, 1978 to Y. Hayashida (cap assembly and method for producing thereof); U.S. Pat. No. 4,298,839, issued Nov. 3, 1981 to P. Johnston (programmable AC electric energy meter having radiation responsive external data interface); U.S. Pat. No. 4,841,805, issued Jun. 27, 1989 to A. Italiano (adjustable cable end coupling); and U.S. Pat. No. 4,889,542, issued Dec. 26, 1989 to W. Hayes (computer air filter device and method).

Additional patents showing air vent baffles or the like include U.S. Pat. No. 5,063,333, issued Nov. 5, 1991 to N. Linden-Smith et al. (discharge tube arrangement); U.S. Pat. No. 5,223,006, issued Jun. 29, 1993 to C. Moran, III (air cleaner box for a computer); U.S. Pat. No. 6,094,194, issued Jul. 25, 2000 to J. Jackson (apparatus and method of providing a controller for selective blocking of cable television programming); U.S. Pat. No. 6,166,394, issued Dec. 26, 2000 to R. Rubscha (dual background document scanner to eliminate hole printouts); U.S. Pat. No. 6,297,956, issued Oct. 2, 2001 to C. Janik et al. (thermally efficient portable computer incorporating deploying CPU module); U.S. Pat. No. 6,324,075, issued Nov. 27, 2001 to E. Unrein et al. (partially covered motherboard with EMI partition gateway); U.S. Pat. No. 6,640,270, issued Oct. 28, 2003 to J. Wang (terminal connection box and plug); Japanese Patent No. 10-133,031, published May 22, 1998 (cable access box); and International Patent No. WO 02/095889, published Nov. 28, 2002 (door and frame with peripheral venting for electronic component cabinet).

None of the above inventions and patents, taken either singly or in combination, is seen to describe the instant invention as claimed. Thus, an electronic device baffle solving the aforementioned problems is desired.

### SUMMARY OF THE INVENTION

The electronic device baffle is located on or within an electronic device, such as a cable converter or a satellite receiver, having a vented cover and electronic motherboard. The baffle is mounted either on top of or below the vented cover and is situated above the motherboard. The baffle is designed to prohibit foreign matter, such as liquids or dust particles, from contacting the motherboard, but without restricting the necessary flow of air through the vented cover.

The baffle has a flat plate and sidewalls extending from the flat plate, and may also have end portions that slope upwardly from the flat plate to the same side as the sidewalls, and which are diametrically opposed to each other. The flat plate, either located beneath or above slots in the vented cover, is adapted to catch dust or dirt that may have entered through the slots when the flat plate is beneath the cover, or block dust and dirt from entering the slots when the flat plate is above the cover. When the baffle has sloping end portions, the end portions are situated outside of the area into which the contaminants would pass, which allows extra space for overflow. A plurality of legs are permanently affixed either to the flat plate or to the sidewalls. The legs attach to the top, or alternatively to the bottom, of the vented cover and support the baffle above the motherboard.

Accordingly, it is a principal object of the invention to prevent contaminants from infecting the motherboard of an electronic device, such as a cable converter or satellite receiver.

It is an additional object of the invention to provide a simple and inexpensive method of protecting the electronic components from damage.

Further, it is an object of the invention to allow individuals to easily determine visually whether contaminants have entered within the device.

It is an object of the invention to provide improved elements and arrangements thereof for the purposes described which is inexpensive, dependable and fully effective in accomplishing its intended purposes.

These and other aspects of the present invention will become readily apparent upon further review of the following specification and drawings.

### DESCRIPTION OF THE DRAWINGS

FIG. 1 is an environmental, perspective view of an electronic device with the housing broken away and in section to show an electronic device baffle according to a first embodiment of the present invention.

FIG. 2 is an environmental top view of the electronic device baffle of the baffle of FIG. 1.

FIG. 3 is a perspective view of the electronic device baffle of FIG. 1.

FIG. 4 is an environmental, perspective view of an electronic device with the housing broken away and in section to show an electronic device baffle according to the first embodiment of the present invention having bendable tabs.

FIG. 5 is an environmental, perspective view of an electronic device baffle according to a second embodiment of the present invention with the baffle broken away to show attachment to the vent of an electronic device.

FIG. 6 is a perspective view of the electronic device baffle according to the second embodiment of the present invention shown from the bottom of the baffle.

Similar reference characters denote corresponding features consistently throughout the attached drawings.

### DETAILED DESCRIPTION OF THE PREFERRED EMBODIMENTS

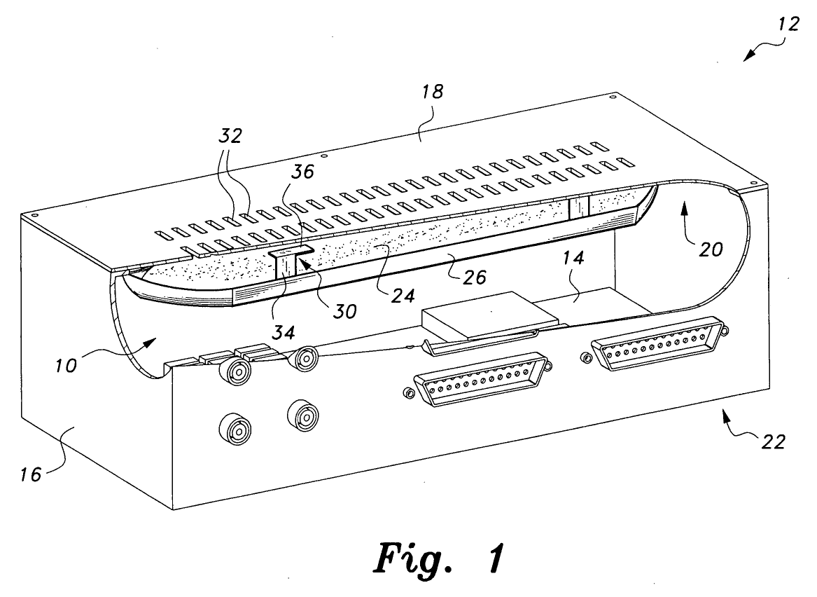

The present invention is a baffle, a first embodiment of which designated generally as 10 in the drawings. Referring to FIGS. 1-4, the baffle 10 may be used with an electronic device 12, for example a cable converter or a satellite receiver. The electronic device 12 includes a motherboard 14 and a housing 16 having a vented cover 18. The vented cover 18 has a plurality of slots 32. The baffle 10 may be mounted on top of the cover 18, preferably, or to the underside 20 of the vented cover 18 as shown in the drawings, and is situated above the motherboard 14. The baffle 10 is designed to prohibit foreign matter, such as liquids or dust, from contacting the motherboard 14, but without restricting the flow of air through the slots 32 in the vented cover 18.

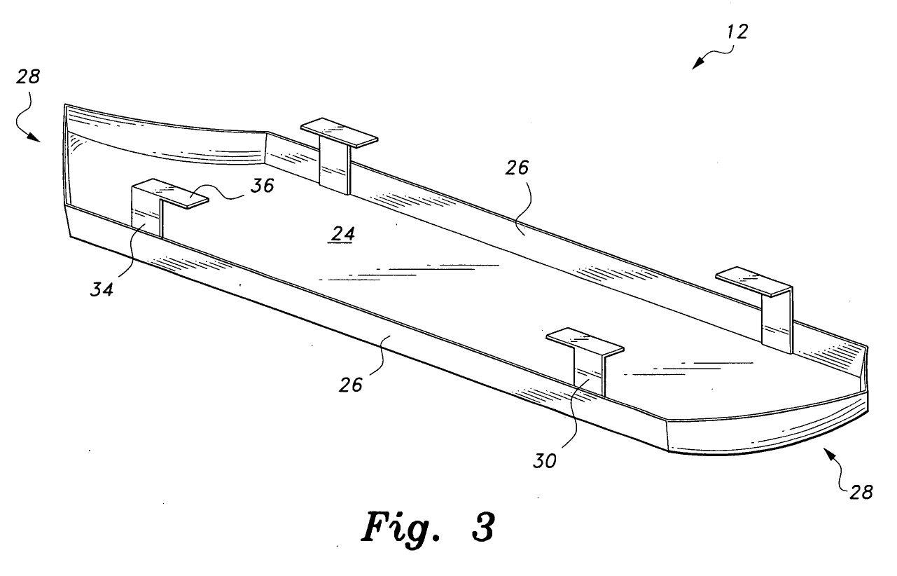

Referring first to FIG. 1, an electronic device 12 with the housing 16 broken away and the baffle 10 mounted to the device 12 is shown. The baffle 10 is shown with dust settled within it. The electronic device 12 has a housing 16. The housing 16 includes a bottom portion 22 on which the motherboard 14 is mounted, and a cover 18 that is vented. The first embodiment of the baffle 10 is attached to the underside 20 of the vented cover 18. The baffle 10 has a flat plate 24, a plurality of sidewalls 26, and a plurality of end portions 28 (shown more clearly in FIG. 3). The plate 24, the plurality of sidewalls 26, and the plurality of end portions 28 are integrally connected to one other. The sidewalls 26 extend from the periphery of the plate 24. The end portions 28 slope upwardly from the flat plate 24 to the same side of the plate 24 as the sidewalls 26, and are diametrically opposed to each other.

A plurality of legs 30 are permanently connected to the baffle 10. The legs 30 may be affixed to the sidewalls 26 or directly to the flat plate 24 of the baffle 10. The legs 30 attach to either the top or the bottom 20 of the vented cover 18 and support the baffle 10 above the motherboard 14. The legs 30 may be attached to the vented cover 18 with double-sided tape. Alternatively, the baffle 10 may be attached to the vented cover 18 by bolting the baffle 10 onto the cover 18.

The flat plate 24 is located underneath the slots 32 so that the plate 24 can catch dust, dirt, liquids, or other contaminants that may have entered through the slots 32. The end portions 28 of the baffle 10 are situated outside of the area into which the contaminants pass, which allows extra space for overflow.

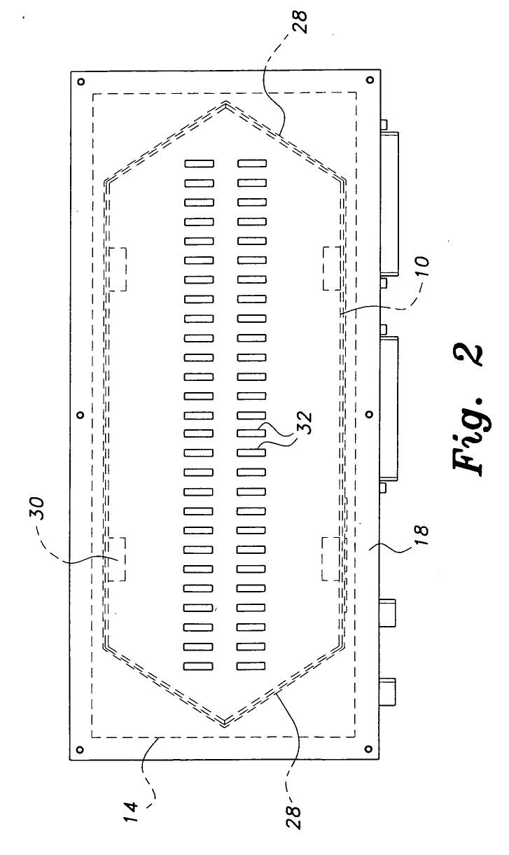

FIG. 2 shows a top view of the baffle 10 (shown in phantom) mounted onto the vented cover 18 by attachment of the baffle legs 30. The baffle 10 is situated beneath the slots 32 defined in the vented cover 18. The flat plate 24 is positioned underneath the cover slots 32, and the end portions 28 of the baffle 10 extend beyond the area under the slots 32 to allow for overflow. An individual is able to look through the slots 32 to determine whether the baffle 10 is filled with contaminants and requires cleaning. The flat plate 24 of the baffle 10 is held above the motherboard 14, protecting the motherboard 14 from dust, dirt and liquid.

FIG. 3 shows a perspective view of the baffle 10 unattached to the housing 16 of the electronic device 12. A plurality of legs 30 are connected to the sidewalls 26 of the baffle 10. Each leg 30 has a support post 34 attached to a sidewall 26 and a mounting tab 36 extending normal to the support post 34. The mounting tab 36 attaches to the vented cover 18. The end portions 28 of the baffle 10 slope up from the flat plate 24 of the baffle 10.

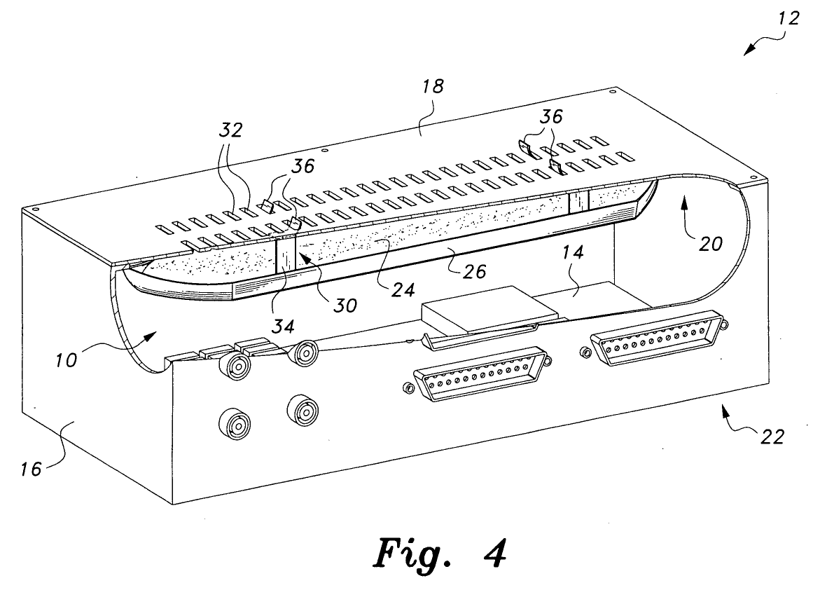

FIG. 4 shows an environmental, perspective view of the electronic device 12 with the housing 16 broken away to show the electronic device baffle 10 attached to the device 12. The mounting tabs 36 attached to the support posts 34 of the legs 30 of the baffle 10 may be bendable, so that the mounting tab 36 of each leg 30 is bent into a slot 32 in the cover 18 to affix the baffle 10 to the vented cover 18. The baffle 10 is therefore attached to the cover 18 and held above the motherboard 14.

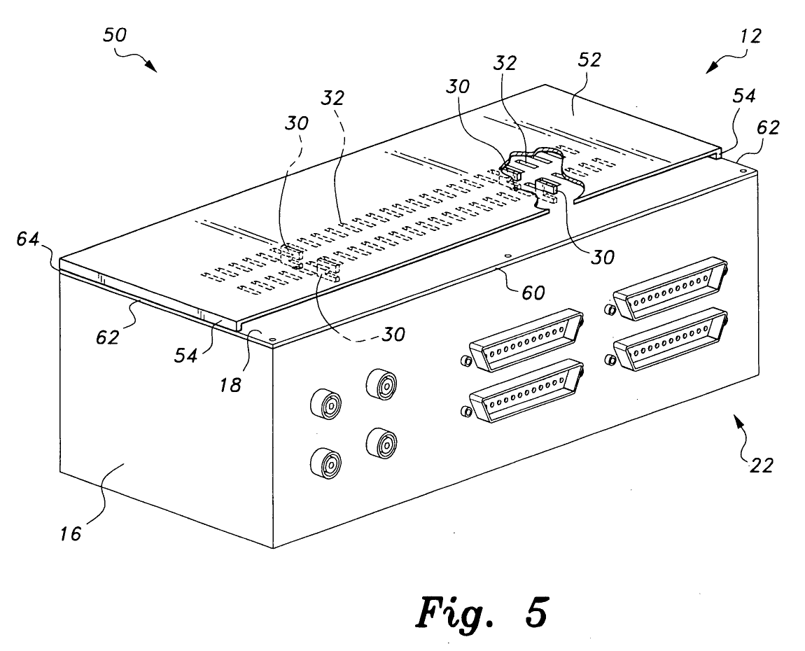

FIG. 5 shows a second embodiment of the electronic device baffle 50. The baffle 50 is adapted to be positioned over the vented cover 18. The baffle 50 has a flat plate 52 and three sidewalls 54 extending from the flat plate 52. When the baffle 50 is placed over the vented cover 18 of the electronic device 12, the three sidewalls 54 cover the front 64 and side edges 62 of the cover 18. The baffle 50 does not require a rear sidewall, since the rear of the baffle 50 is recessed from the rear edge 60 of the electronic device 12, and also to provide an opening for airflow to reach the slots 32 to provide ventilation. Since the rear edge 60 of the device 12 often faces a wall, it is less prone to receive dust circulated throughout a room.

A plurality of legs 30 are affixed to the flat plate 52 and extend downward when the baffle 50 is placed over the vented cover 18. Each of the legs 30 is adapted to fit within a slot 32 in the vented cover 18. When the baffle 50 is placed over the cover 18, the legs 30 are slid within the slots 32 and the electronic device baffle 50 is suspended over the vented cover 18. The plate 52 is supported sufficiently above the slots 32 in the vented cover 18, thereby allowing for adequate ventilation.

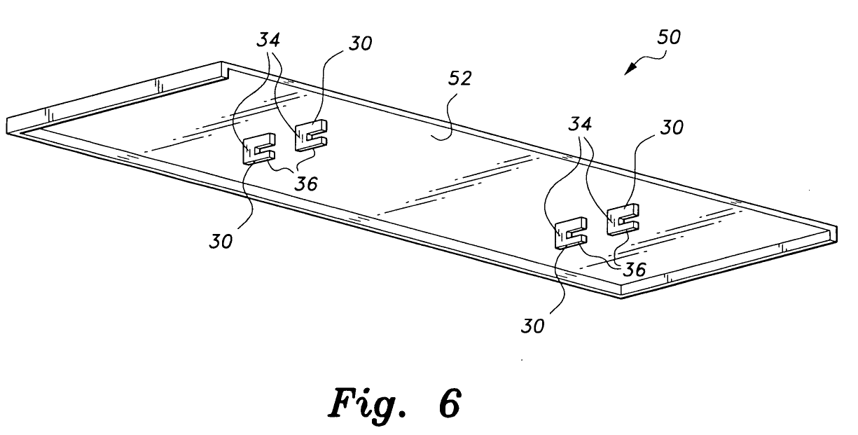

Turning now to FIG. 6, the bottom of the electronic device baffle 50 is shown. The baffle 50 includes a flat plate 52 and three sidewalls 54 extending normal to three sides of the periphery of the plate 52. A plurality of legs 30 extend from the flat plate 52 and are adapted to slide within the slots 32 in the vented cover 18. Each leg 30 has a support post 34 attached to the bottom of the flat plate 52 and a mounting tab 36 extending normal to the support post 34. The mounting tab 36 attaches to slots 32 in the vented cover 18. The mounting tabs 36 may be solid or flexible, depending on the material used. The legs 30 may be made from plastic or any other type of material suitable for attachment to the vented cover 18.

It is to be understood that the present invention is not limited to the embodiments described above, but encompasses any and all embodiments within the scope of the following claims.

1. A baffle adapted for use with an electronic device having a vented cover with a plurality of slots and having a motherboard, the baffle comprising:
a flat plate having a periphery;
at least one sidewall normal to the flat plate extending around the periphery of the flat plate;
a plurality of end portions integrally connected to the flat plate and the at least one sidewall, the end portions sloping upwardly from the flat plate to the same side of the plate as the at least one sidewall; and
a plurality of legs extending to the same side of the flat plate as the at least one sidewall, the legs being dimensioned and configured for attachment to the vented cover of the electronic device.

2. The baffle according to claim 1, wherein said plurality of legs are attached to and extend from said at least one sidewall.

3. The baffle according to claim 1, wherein said plurality of legs are attached to and extend from the flat plate.

4. The baffle according to claim 1, further comprising means for attaching the plurality of legs to the vented cover.

5. The baffle according to claim 4, wherein said means for attaching comprises a plurality of bendable mounting tabs attached to the legs, the mounting tabs being adapted for engaging the slots in the vented cover.

6. The baffle according to claim 1, wherein the means for attaching the legs to the vented cover comprises a plurality of bolts adapted for connecting the mounting tabs of the legs directly to the vented cover.

7. The baffle according to claim 4, wherein the means for attaching the legs to the vented cover comprises an adhesive adapted for attaching the mounting tabs of the legs directly to the vented cover.

8. The baffle according to claim 1, further comprising means for attaching the legs to the cover of the electronic device above the slots.

9. The baffle according to claim 1, further comprising means for attaching the legs to the cover of the electronic device below the slots.

10. A baffle adapted for use with an electronic device having a vented cover with a plurality of slots and a motherboard, the baffle comprising:
a flat plate having a periphery;
three sidewalls extending from the periphery of the flat plate normal to the flat plate; and
a plurality of legs extending from the flat plate, the legs being dimensioned and configured for attachment to the vented cover of the electronic device.

11. The baffle according to claim 10, further comprising means for attaching the plurality of legs to the vented cover.

12. The baffle according to claim 11, wherein the means for attaching comprises a plurality of bendable mounting tabs attached to the legs, the mounting tabs being adapted for engaging the slots.

13. The baffle according to claim 11, wherein the means for attaching comprises a plurality of bolts adapted for connecting the mounting tabs of the legs directly to the vented cover.

14. The baffle according to claim 11, wherein the means for attaching comprises an adhesive adapted for attaching the mounting tabs of the legs directly to the vented cover.
